(19) United States
(12) Patent Application Publication
(10) Pub. No.: US 2008/0297302 A1
(43) Pub. Date: Dec. 4, 2008

(54) ON CHIP ZINC OXIDE THIN FILM VARISTOR, FABRICATION METHOD THEREOF AND APPLICATIONS THEREOF

(76) Inventors: Liann-Be CHANG, Kwei-Shan (TW); Uan-Hsong CHANG, Kwei-Shan (TW)

Correspondence Address: SINORICA, LLC, 528 FALLSGROVE DRIVE, ROCKVILLE, MD, 20850, US

(21) Appl. No.: 12/129,733

(22) Filed: May 30, 2008

(30) Foreign Application Priority Data
Jun. 1, 2007 (TW) 096119700

(51) Int. Cl. H01C 7/10; C23C 14/34

(52) U.S. Cl. 338/21; 204/192.25

(57) ABSTRACT

The present invention discloses an on chip zinc oxide thin film varistor, a fabrication method thereof and applications thereof. In the present invention, a zinc oxide-containing film is directly formed on a substrate with a sputtering method, and then the zinc oxide-containing film is processed with a post-annealing treatment to raise the resistance thereof. Thus, an on chip zinc oxide thin film varistor having a superior performance is attained. The fabrication process of the present invention is easy to control and has a high reliability. Further, the fabrication process of the present invention can fully integrate with the semiconductor processes, which benefits the surge protection of semiconductor components.

### BACKGROUND OF THE INVENTION

1. Field of the Invention

The present invention relates to a surge protection component, particularly to an on chip zinc oxide thin film varistor, a fabrication method thereof and applications thereof.

2. Description of the Related Art

With the advance of science and technology, IC control components have been widely used in traditional and high-tech electronic products. IC components can indeed promote performance and reduce size. However, IC components are intrinsically weaker in surge resistance. Therefore, some surge absorption elements are added to IC components lest surge damage IC components.

Varistors have been extensively used in surge protection. A varistor prevents electronic components from being damaged by surge via absorbing surge and lowering the voltage to a safe level. A traditional ceramic varistor is made of a zinc oxide (ZnO)-based block containing several types of metal oxides, and the ZnO-based block is usually fabricated with a sintering method currently. Such a type of ZnO-based varistor has a high nonlinear coefficient (α≧50) and a superior reliability and has some commercial applications. However, the sintering method of the traditional ceramic varistor is hard to be incorporated with the semiconductor processes and thus restricts the application thereof.

### SUMMARY OF THE INVENTION

The primary objective of the present invention is to provide an on chip zinc oxide thin film varistor, a fabrication method thereof and applications thereof to solve the abovementioned problems, wherein the on chip zinc oxide thin film varistor is fabricated with a sputtering method and a post-annealing process, which are easy to integrate with the semiconductor processes, whereby the fabrication process is simplified, the cost is reduced, and the abovementioned conventional problems are overcome.

To achieve the abovementioned objective, the present invention proposes an on chip zinc oxide thin film varistor and a fabrication method thereof. The method of the present invention comprises steps: placing a substrate in a sputtering system; depositing a zinc oxide (ZnO)-containing film on the substrate with an RF (Radio Frequency)-sputtering method, wherein an aluminum oxide (AlO₃)-doped ZnO material is used as the sputtering target; and post-annealing the ZnO-containing film to obtain the on chip zinc oxide thin film varistor of the present invention. The on chip zinc oxide thin film varistor of the present invention can successfully absorb surge and stabilize voltage. Therefore, the present invention can prevent electronic components from being damaged by surge. Further, the sputtering method and post-annealing process used in the present invention are easy to integrate with common semiconductor process. Therefore, the present invention can provide an effective surge protection for semiconductor components.

Below, the present invention is described in detail in cooperation with the drawings to make easily understood the objectives, characteristics and functions of the present invention.

### BRIEF DESCRIPTION OF THE DRAWINGS

FIGS. 1A-1D are sectional views schematically showing a method for fabricating an on chip zinc oxide thin film varistor according to one embodiment of the present invention;

FIG. 2 is a diagram showing the I-V relationship of an on chip zinc oxide thin film varistor according to one embodiment of the present invention; and

FIG. 3 and FIG. 4 are diagrams schematically showing the surge-resistant semiconductor components using the on chip zinc oxide thin film varistor of the present invention as a surge protection element.

### DETAILED DESCRIPTION OF THE INVENTION

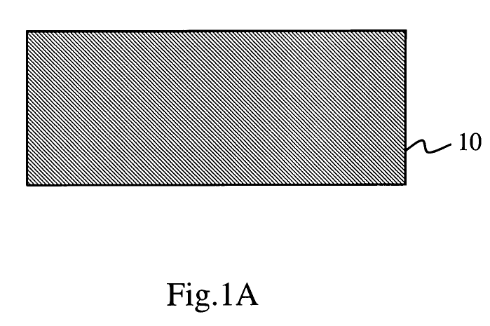

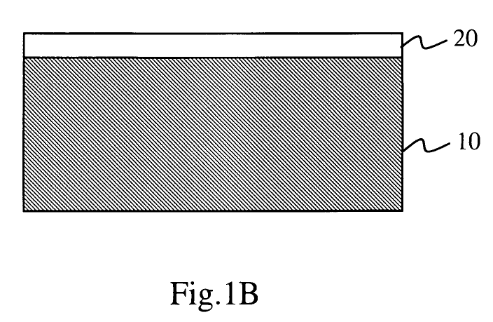

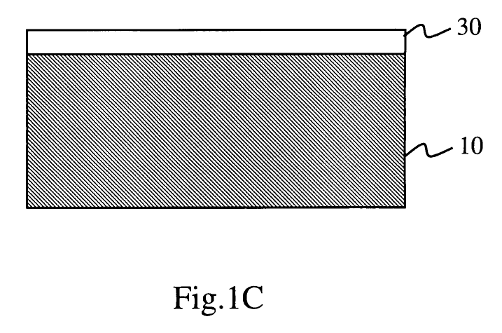

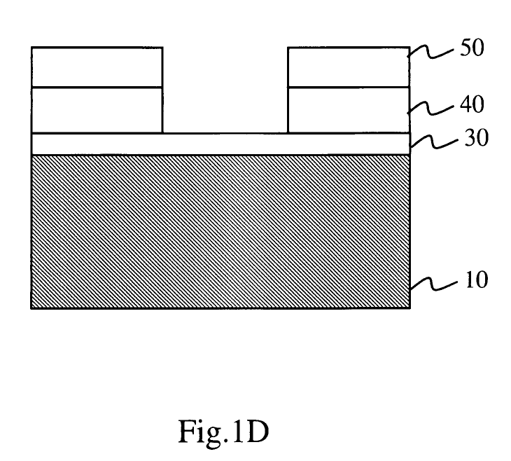

Refer to FIGS. 1A-1D sectional views schematically showing a method for fabricating an on chip zinc oxide thin film varistor according to one embodiment of the present invention.

In this embodiment, the ZnO film is deposited with an RF-sputtering machine. Refer to FIG. 1A. Firstly, the impurities and particles on a silicon substrate 10 are removed with a cleaning process, such as flushed with deionized water and cleaned with an ultrasonic vibrator. Refer to FIG. 1B. In the sputtering system, an AlO₃-doped ZnO material is used as the sputtering target, wherein AlO₃ has a concentration of 2 wt % and a purity of 99.99%. RF (Radio Frequency) energy is applied to sputter the target, and a ZnO-containing film 20 is thus deposited on the silicon substrate 10. Refer to FIG. 1C. The ZnO-containing film 20 is processed with a post-annealing treatment. In this embodiment, the annealing temperature is 800° C. The annealed ZnO-containing film 30 has a superior varistor performance, which will be further described thereinafter. Refer to FIG. 1D. Conductive materials, such as titanium and gold, are deposited on the annealed ZnO-containing film 30 to form electrodes containing a titanium conductive layer 40 and a gold conductive layer 50.

In this embodiment, the ZnO-containing film is directly formed with a sputtering method and then processed with a post-annealing treatment, whereby the properties of the ZnO-containing film can be easily controlled, and a high-stability ZnO-containing film will be attained. The post-annealing treatment will raise the resistance of the ZnO-containing film to several tens of thousands of ohms. Under a lower voltage, the high resistance of the ZnO-containing film can effectively retard current flowing through the ZnO-containing film. Under a high voltage, the resistance of the ZnO-containing film will descend rapidly, and surge will pass through the ZnO-containing film, and the energy of surge will be dissipated in a form of heat. Thus, electronic components are exempted from being damaged by surge. General to speak, almost all the electronic products needing voltage stabilization may use the on chip zinc oxide thin film varistor of the present invention. Therefore, the present invention applies to communication devices, semiconductor protection devices, power transmission systems, control systems, etc.

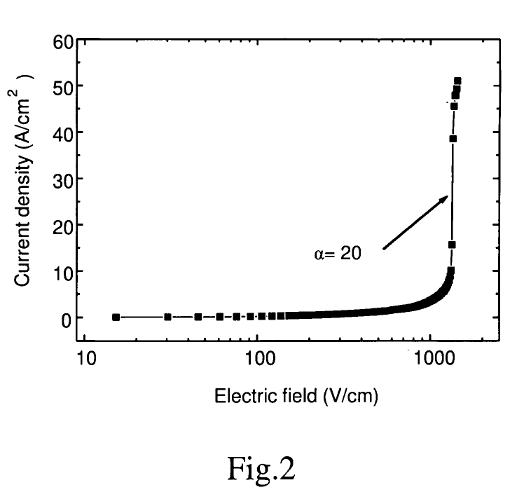

From the I-V relationship shown in FIG. 2, it is observed that the on chip zinc oxide thin film varistor, which is post-annealed at an annealing temperature of 600° C., has a nonlinear coefficient (α) of as high as 20 under a high voltage of 1.2 kV/cm. The on chip zinc oxide thin film varistor with the nonlinear characteristic at a high voltage is especially suitable to function as a surge protection device of a current-sensitive electronic component, such as a power HEMT (High Electron Mobility Transistor), or LED (Light Emitting Diode). As the on chip zinc oxide thin film varistor can effectively dissipate heat generated by a great input current, it can drain a current with a density of as high as 50 A/cm².

The sputtering process and post-annealing process used in the method of the present invention are exactly the processes generally used in semiconductor fabrication. Therefore, the method of the present invention can easily integrate with the semiconductor processes. Thus, the present invention can provide an effective surge protection for semiconductor components.

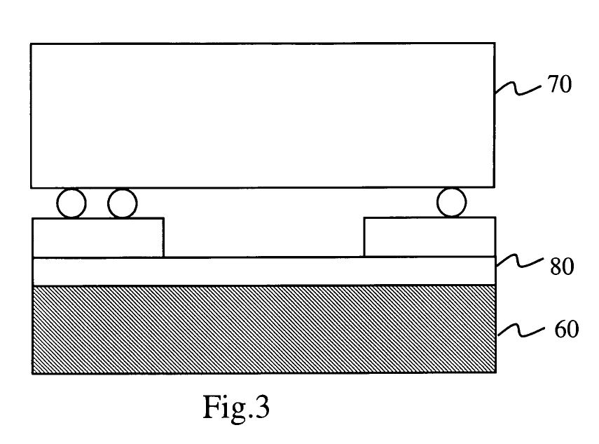

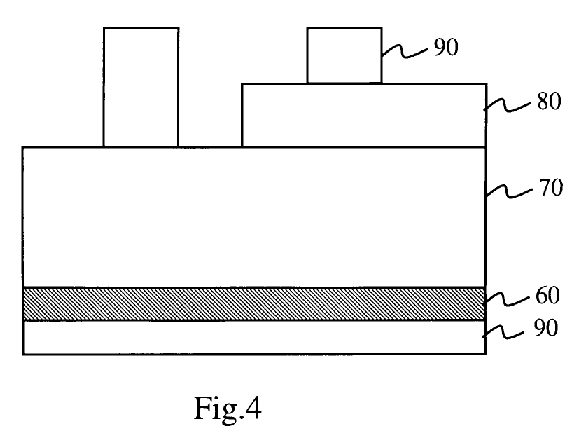

Refer to FIG. 3 a diagram schematically showing a surge-resistant semiconductor component using the on chip zinc oxide thin film varistor of the present invention as a surge protection element, wherein a LED chip is used to exemplify the semiconductor component. The surge-resistant semiconductor component comprises: a conductive or non-conductive substrate 60, a LED 70 and a ZnO-containing film 80. Firstly, the ZnO-containing film 80 is formed on the substrate 60 with a sputtering method and a post-annealing treatment. Then, the LED 70 is installed on the ZnO-containing film 80 with a flip chip technology. Thereby, the ZnO-containing film 80 can release surge current for the LED 70 and exempt the LED 70 from damage by surge. Refer to FIG. 4. The ZnO-containing film 80 may be alternatively formed on the other side of the LED 70 and can still attain the same effect. In this embodiment, conductive layers 90 are formed on two sides of the entire surge-resistant semiconductor component. In the present invention, the abovementioned semiconductor component may be a silicon semiconductor component or a compound semiconductor component.

The embodiments described above are only to exemplify the present invention but not to limit the scope of the present invention. Therefore, any equivalent modification or variation according to the spirit of the present invention is to be also included within the scope of the present invention, which is based on the claims stated below.

What is claimed is:

1. A method for fabricating an on chip zinc oxide thin film varistor, comprising steps:
providing a substrate;
forming a zinc oxide (ZnO)-containing film on said substrate with a sputtering method; and
processing said zinc oxide-containing film with a post-annealing treatment.

2. The method for fabricating an on chip zinc oxide thin film varistor of claim 1, wherein said sputtering method adopts an aluminum oxide (AlO₃)-doped ZnO-based material as a sputtering target and applies radio frequency energy to sputter said sputtering target and attain said zinc oxide-containing film.

3. The method for fabricating an on chip zinc oxide thin film varistor of claim 1, wherein said post-annealing treatment is undertaken below a temperature of 800° C.

4. An on chip zinc oxide thin film varistor fabricated by the following steps:
providing a substrate;
forming a zinc oxide (ZnO)-containing film on said substrate with a sputtering method; and
processing said zinc oxide-containing film with a post-annealing treatment.

5. The on chip zinc oxide thin film varistor of claim 4, wherein said substrate is a conductive substrate or a non-conductive substrate.

6. The on chip zinc oxide thin film varistor of claim 4 further comprising a plurality of electrodes formed on said zinc oxide-containing film.

7. The on chip zinc oxide thin film varistor of claim 6, wherein said electrodes is made of a conductive materials.

8. An on chip surge-resistant semiconductor component, comprising:
a substrate;
a zinc oxide (ZnO)-containing film formed on said substrate with a sputtering method and a post-annealing treatment; and
a semiconductor chip arranged or flipped on said zinc oxide-containing film.

9. The on chip surge-resistant semiconductor component of claim 8, wherein said substrate is a conductive substrate or a non-conductive substrate.

10. The on chip surge-resistant semiconductor component of claim 8, wherein said semiconductor chip is a silicon semiconductor component or a compound semiconductor component.

11. An on chip surge-resistant semiconductor component, comprising:
a substrate:
a semiconductor chip installed on said substrate; and
a zinc oxide (ZnO)-containing film formed on said semiconductor chip with a sputtering method and a post-annealing treatment.

12. The on chip surge-resistant semiconductor component of claim 11, wherein said substrate is a conductive substrate or a non-conductive substrate.

13. The on chip surge-resistant semiconductor component of claim 11, wherein said semiconductor chip is a silicon semiconductor component or a compound semiconductor component.
